(19) United States
(12) Patent Application Publication
(10) Pub. No.: US 2017/0048966 A1
(43) Pub. Date: Feb. 16, 2017

(54) Radar sensor

(71) Applicant: InnoSenT GmbH, Donnersdorf (DE)

(72) Inventors: Stefan Bäuerlein, Dingolshausen (DE); Thilo Lenhard, Hallstadt (DE)

(73) Assignee: InnoSenT GmbH, Donnersdorf (DE)

(21) Appl. No.: 15/235,148

(22) Filed: Aug. 12, 2016

(30) Foreign Application Priority Data
Aug. 12, 2015 (DE) 10 2015 215 398.3

(51) Int. Cl. H05K 1/02

(52) U.S. Cl. CPC H05K 1/0216; G01S 2007/028

(57) ABSTRACT

The invention relates to a radar sensor having a printed circuit board which has an electronic circuit and is equipped with electronic components, and having a shielding cover which covers the printed circuit board and the equipment arranged on said printed circuit board, wherein the shielding cover is formed from a printed circuit board material and has a recess which creates space for accommodating the equipment.

### TECHNICAL FIELD

The invention relates to a radar sensor, such as, in particular, for a motor vehicle or for other applications.

### PRIOR ART

Radar sensors are used more and more frequently, in particular for motor vehicles, in order to provide information about the area surrounding the motor vehicle for driver assistance systems.

Radar sensors of this kind have a housing with a printed circuit board arranged therein, said printed circuit board having an electronic circuit with electronic equipment, wherein at least one antenna and connection elements are also provided. In this case, a conductive cover is usually fitted onto the housing or onto the printed circuit board, so that RF shielding and possibly EMC shielding can be provided.

In this case, production and assembly of a conductive cover of this kind are complicated and therefore costly.

### SUMMARY OF THE INVENTION, OBJECT, SOLUTION AND ADVANTAGES

The object of the invention is to provide a radar sensor which is of simple and cost-effective construction and nevertheless is also easy to assemble.

The object is achieved by the features of claim 1. One exemplary embodiment of the invention relates to a radar sensor having a printed circuit board which has an electronic circuit and is equipped with electronic components, and having a shielding cover which covers the printed circuit board and the equipment arranged on said printed circuit board, wherein the shielding cover is formed from a printed circuit board material and has a recess which creates space for accommodating the equipment. As a result, a shielding cover can be produced in a simple manner, it being possible for said shielding cover to also be connected and to be soldered to the printed circuit board using an SMD process. As a result, the production process can be automated to a greater extent, this lowering costs. In this case, equipping means, in particular, equipping with electronic components.

It is particularly advantageous when the shielding cover consists of a single-ply or multiple-ply printed circuit board material. This can improve the stability and also the shielding depending on the demands made of the shielding of the shielding cover, and therefore a single- or multiple-ply printed circuit board material can be used.

In this case, it is particularly advantageous when the single-ply or multiple-ply printed circuit board material contains a single-ply or multiple-ply electrically conductive layer and contains at least one single-ply or multiple-ply non-conductive layer. As a result, the shielding can be improved on account of the one or more electrically conductive layers.

It is particularly advantageous when the recess is a cutout which is made in the material of the printed circuit board, in particular by milling. As a result, a cover with a recess can be produced from a planar printed circuit board, so that the base material of the printed circuit board can be acquired in a cost-effective manner as a mass-produced product.

It is also advantageous when the shielding cover has electrically conductive contact areas which has for solder-connection of the shielding cover to the printed circuit board and/or to other components and/or printed circuits. As a result, the shielding cover can be soldered to other elements in a simple manner, without additional measures or connecting elements being required.

It is also advantageous when the shielding cover has contact areas on one side or both sides of its inner face and/or of its outer face. As a result, connections to other elements can be can be established in a simple manner.

It is also advantageous when the shielding cover has at least one electrically conductive contact-connection between contact areas on the inner face and on the outer face. This can also be achieved by a plated-through hole when an electrical connection is produced on the inner face, it being possible for contact to be made with an element from the outside at said electrical connection.

It is also advantageous when the at least one electrically conductive contact-connection between contact areas on the inner face and on the outer face runs along the circumferential edge of the shielding cover. Contact-connections can therefore be produced and connected from outside in a simple manner, such as by means of SMD technology for example.

It is also advantageous when electrically conductive contact areas are provided along the circumferential edge of the shielding cover.

In this case, it is also advantageous when the shielding cover is provided with a metallized layer on its inner face of the recess. This improves the shielding properties.

Further advantageous refinements are described by the following description of the figures and by the dependent claims.

### BRIEF DESCRIPTION OF THE DRAWINGS

The invention will be explained in greater detail below on the basis of at least one exemplary embodiment with reference to the drawings, in which:

FIG. 1 shows a schematic view of a radar sensor according to the prior art,

FIG. 2 is a schematic illustration of one face of a shielding cover,

FIG. 3 is a schematic illustration of the other face of the shielding cover according to FIG. 2,

FIG. 4 is a schematic illustration of one face of a further shielding cover, and

FIG. 5 is a schematic illustration of the other side of the shielding cover according to FIG. 4.

### PREFERRED EMBODIMENT OF THE INVENTION

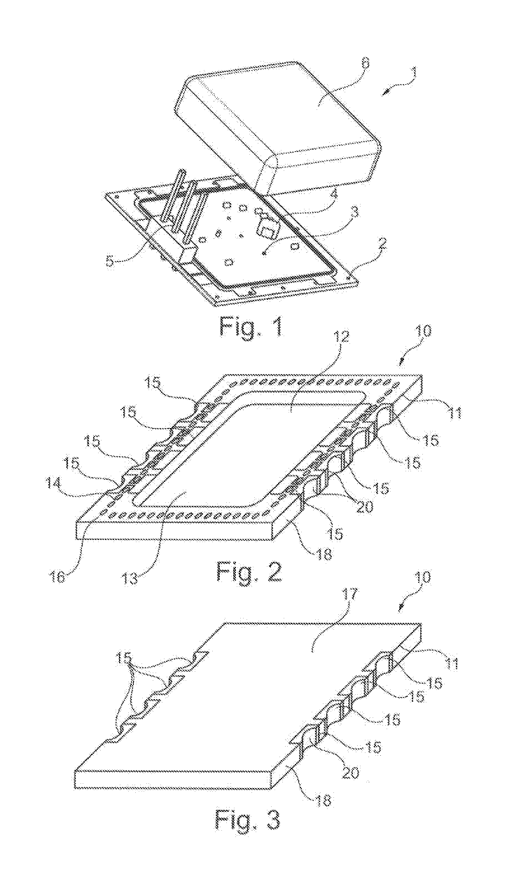

FIG. 1 shows a radar sensor 1 according to the prior art. The radar sensor 1 is provided with an RF printed circuit board 2 which has an electronic circuit 3 and is equipped with electronic components 4. In this case, connection pins 5 are also provided by way of example, said connection pins being connected to the printed circuit board 2. Furthermore, a shielding cover 6 which covers the printed circuit board 2 and the equipment arranged on said printed circuit board is provided, it being possible for said shielding cover to be connected to the printed circuit board 2.

The shielding cover 6 is in the form of a hollow body which is open at one face and is electrically conductive. This shielding cover 6 can be connected to the printed circuit board 2, this being a relatively complex and therefore also expensive assembly process.

FIGS. 2 and 3 show a shielding cover 10 according to the invention which is formed from a printed circuit board material 11 and has a recess 12 which can accommodate the equipment of the printed circuit board. The rear face of the shielding cover is shown in FIG. 3. Said rear face is of substantially planar design. In this case, the recess 12 is a cutout which is made in the material 11 of the printed circuit board, in particular by milling, such as deep milling. As a result, a kind of basin-like volume is produced in the printed circuit board of the shielding cover 10, said volume being formed by a base 13 and a circumferential wall 14.

According to the invention, it is advantageous when the shielding cover 10 consists of a single-ply or multiple-ply printed circuit board material 11. In this case, the single-ply or multiple-ply printed circuit board material 11 can contain a single-ply or multiple-ply electrically conductive layer and at least one single-ply or multiple-ply non-conductive layer.

For the purpose of connecting the shielding cover 10, for example, to a printed circuit board, electrically conductive contact areas 15 are provided, which electrically conductive contact areas has for solder-connection of the shielding cover 10 to the printed circuit board and/or to other components and/or printed circuits. FIGS. 2 and 3 show that the shielding cover 10 has contact areas 15 on one side or both sides of its inner face 16 and/or of its outer face 17. In this case, the contact areas are metallic surface elements which serve for soldering or electrically conductive adhesive-bonding purposes.

In this case, the contact areas 15 can be designed such that they extend over the edge 18 of the shielding cover 10. In this case, the shielding cover 10 advantageously and optionally has at least one electrically conductive contact-connection 20 between contact areas 15 on the inner face 16 and on the outer face 17. In this respect, FIGS. 2 and 3 show that the at least one electrically conductive contact connection 20 between contact areas 15 on the inner face 16 and on the outer face 17 runs along the circumferential edge 18 of the shielding cover 10.

The electrically conductive contact-connections 20, which are arranged along the circumferential edge 18 of the shielding cover 10, can also be provided in the form of electrically conductive contact areas.

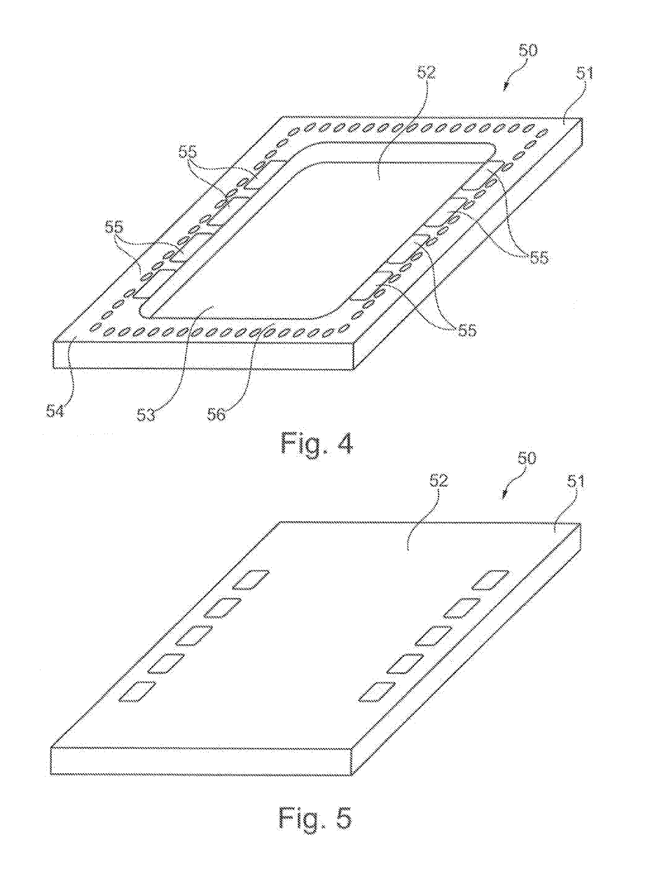

FIGS. 4 and 5 show a further shielding cover 50 according to the invention which is formed from a printed circuit board material 51 and has a recess 52 which can accommodate the equipment of the printed circuit board. The rear face of the shielding cover is shown in FIG. 5. Said rear face is of substantially planar design. In this case, the recess 52 is a cutout which is made in the material 51 of the printed circuit board, in particular by milling, such as deep milling. As a result, a kind of basin-like volume is produced in the printed circuit board of the shielding cover 50, said volume being formed by a base 53 and a circumferential wall 54.

According to the invention, it is advantageous when the shielding cover 50 consists of a single-ply or multiple-ply printed circuit board material 51. In this case, the single-ply or multiple-ply printed circuit board material 51 can contain a single-ply or multiple-ply electrically conductive layer and at least one single-ply or multiple-ply non-conductive layer.

For the purpose of connecting the shielding cover 50, for example, to a printed circuit board, electrically conductive contact areas 55 are provided, which electrically conductive contact areas has for solder-connection of the shielding cover 50 to the printed circuit board and/or to other components and/or printed circuits. FIGS. 4 and 5 show that the shielding cover 50 has contact areas 55 on one side or several sides or optionally both sides of its inner face 56 and/or of its outer face 57. In this case, the contact areas are metallic surface elements which serve for soldering purposes.

In addition to the metallic layers of the printed circuit board material 11, 51, the shielding cover 10, 50 can also be provided with a metallized layer on its inner face of the recess 12, 52 as an alternative or optionally in addition.

1. Radar sensor having a printed circuit board which has an electronic circuit and is equipped with electronic components, and having a shielding cover which covers the printed circuit board and the equipment arranged on said printed circuit board, wherein the shielding cover is formed from a printed circuit board material and has a recess which creates space for accommodating the equipment.

2. Radar sensor according to claim 1 wherein the shielding cover consists of a single-ply or multiple-ply printed circuit board material.

3. Radar sensor according to claim 2, wherein the single-ply or multiple-ply printed circuit board material contains a single-ply or multiple-ply electrically conductive layer and contains at least one single-ply or multiple-ply non-conductive layer.

4. Radar sensor according to claim 1, wherein the recess is a cutout which is made in the material of the printed circuit board, in particular by milling.

5. Radar sensor according to claim 1. wherein the shielding cover has electrically conductive contact areas which has for solder-connection of the shielding cover to the printed circuit board and/or to other components and/or printed circuits.

6. Radar sensor according to claim 5, wherein the shielding cover has contact areas on one side or several sides of its inner face and/or of its outer face.

7. Radar sensor according to claim 5, wherein that the shielding cover has at least one electrically conductive contact-connection between contact areas on the inner face and on the outer face.

8. Radar sensor according to claim 1, wherein the at least one electrically conductive contact-connection between contact areas on the inner face and on the outer face runs along the circumferential edge of the shielding cover.

9. Radar sensor according to claim 1, wherein electrically conductive contact areas are provided along the circumferential edge of the shielding cover.

10. Radar sensor according to claim 1, wherein the shielding cover is provided with a metallized layer on its inner face of the recess.
